(19) United States
(12) Patent Application Publication
(10) Pub. No.: US 2009/0130601 A1
(43) Pub. Date: May 21, 2009

(54) METHOD FOR FABRICATING SEMICONDUCTOR DEVICE

(76) Inventor: Young-Doo Jeon, Bucheon-si (KR)

Correspondence Address: SHERR & VAUGHN, PLLC, 620 HERNDON PARKWAY, SUITE 200, HERNDON, VA, 20170, US

(21) Appl. No.: 12/267,567

(22) Filed: Nov. 8, 2008

(30) Foreign Application Priority Data
Nov. 16, 2007 (KR) 10-2007-0117290

(51) Int. Cl. H01L 21/02; G03F 7/20

(52) U.S. Cl. 430/312; 430/323

(57) ABSTRACT

A method for fabricating a semiconductor device may include forming first and second photoresist patterns that intersect with each other on and/or over an etched film, and forming a fine pattern on the etched film by etching the etched film using the first and second photoresist patterns as an etching mask. According to embodiments, a fine pattern, such as a contact hole, may be formed by performing two exposure processes. The method may use existing masks for line and/or space. The method may secure a sufficient etching margin by securing a sufficient thickness of a photoresist film through two photoresist coating processes.

The present application claims priority under 35 U.S.C. 119 to Korean Patent Application No. 10-2007-0117290 (filed on Nov. 16, 2007), which is hereby incorporated by reference in its entirety.

### BACKGROUND

A photo lithography process may be an important process in fabricating a semiconductor device. In a photo lithography process, a photoresist may be uniformly coated on and/or over a wafer, and an exposure process may then be performed on and/or over the photoresist using a photomask. The photomask may be formed in a predetermined lay-out and the exposed photoresist may then be developed to form a pattern having a certain shape. In a semiconductor photo lithography technique, a mask that may be used in a photo lithography process of fabricating a semiconductor device may have an elaborate design. This may assist in controlling a quantity of light transmitted through a mask. As semiconductors have become more highly integrated, a design rule may become increasingly fine and complicated. A line width of a photoresist pattern may also become smaller. However, certain technical limitations, such as constructive interference of light, an exposure apparatus, and the like, may make it difficult to form a fine pattern such as a contact hole.

### SUMMARY

Embodiments relate to a method for fabricating a semiconductor device. Embodiments relate to a method for fabricating a semiconductor device which may include forming a fine pattern. Embodiments relate to a method of fabricating a semiconductor device which may include fabricating a fine pattern by performing two exposure processes.

According to embodiments, a method for fabricating a semiconductor device may include at least one of the following. Forming first and second photoresist patterns intersected with each other and stacked on and/or over an etched film. Forming a fine pattern on and/or over the etched film by etching the etched film using the first and second photoresist patterns as an etching mask.

According to embodiments, a method for fabricating a semiconductor device may include at least one of the following. Forming a dielectric film on and/or over a semiconductor substrate. Forming and patterning a first photoresist film on and/or over the dielectric film to form a first photoresist pattern in a first direction. Forming and patterning a second photoresist film on and/or over the dielectric film on and/or over which the first photoresist pattern may be formed to form a second photoresist pattern in a second direction intersecting with the first direction. Etching the dielectric film using the first and second photoresist patterns as an etching mask.

### DRAWINGS

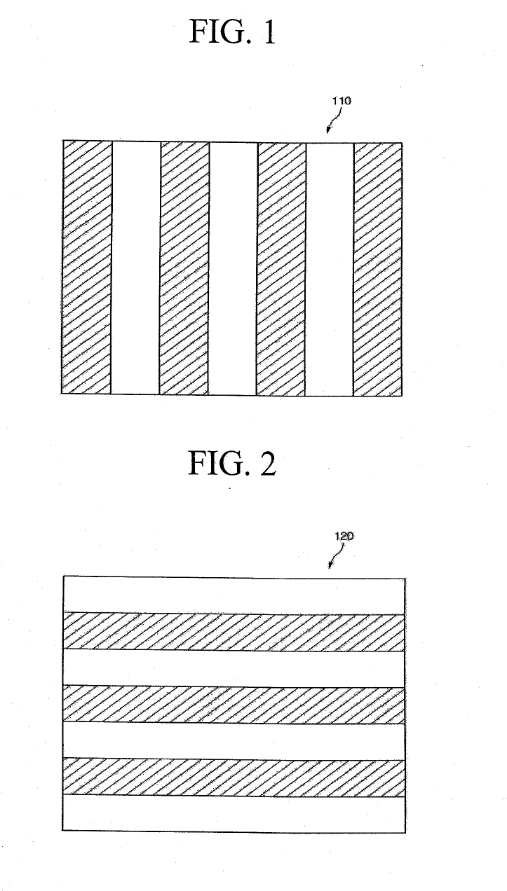

Example FIGS. 1 to 12 illustrate a semiconductor device and a method of fabricating a semiconductor device in accordance with embodiments.

### DESCRIPTION

A method for fabricating a semiconductor device according to embodiments will be described with reference to the drawings. Example FIGS. 1 and 2 are plan views showing a photomask that may be used in fabricating a semiconductor device, according to embodiments.

Referring to example FIG. 1, first mask 110, which may have a line/space pattern, may be used to fabricate a semiconductor device according to embodiments. As shown in example FIG. 2, second mask 120, which may have a line/space pattern, may be used to fabricate a semiconductor device according to embodiments. Fine patterns such as a contact hole of a semiconductor device may be formed by disposing the lines/spaces of first mask 110 and second mask 120 to substantially perpendicularly intersect with each other. According to embodiments, at least one of horizontal and vertical line widths of fine patterns, such as a contact hole or the like, may be controlled by at least one of a width of a line and space of first mask 110 and a width of a line and space of second mask 120.

According to the related art, a photoresist may have been exposed using a photomask having a contact hole-shaped rectangular pattern. Therefore, a rectangular pattern of the photomask may be fine and constructive interference of light passing therethrough may occur. This may limit developing an exposure apparatus that may supplement the constructive interference of light. Hence, good grade fine patterns may not have been formed. According to embodiments, however, fine patterns may be implemented using first and second masks 110 and 120 having line and/or space patterns. Respective widths of line and space of first and second masks 110 and 120 may be set as approximately 30 nm to 100 nm. According to embodiments, at least one of horizontal and vertical line widths of a contact hole may be formed as approximately 30 nm to 100 nm. However, widths of a line and space may not limited to that range. According to embodiments, they may also be formed to different dimensions according to a line width and an interval of a contact hole to be formed.

Separate first and second masks 110 and 120 may not need to be prepared. According to embodiments, first mask 110 may be used as second mask 120. According to embodiments, an existing mask for line/space in forming a fine pattern may be used. This may make it possible to reduce development costs and investment costs rendered in developing and introducing a method for forming a new pattern. According to embodiments, a grade of a photoresist pattern for forming a fine pattern may be excellent. This may make it possible to prevent defects while an etching process is performed using the photoresist pattern, and may also improve a yield.

A method for fabricating a semiconductor device according to embodiments will be described. According to embodiments, a method may fabricate fine patterns using first and second photomasks 110 and 120 shown in example FIGS. 1 and 2. First and second photoresist patterns, which may intersect with each other, may be formed so as to be stacked on and/or over an etched film. According to embodiments, an etched film may be etched using the first and second photoresist patterns as an etching mask. This may form fine patterns on and/or over the etched film. The first photoresist pattern may be formed through exposure and development processes using first mask 110 shown in example FIG. 1. The second photoresist pattern may be formed through exposure and development processes using second mask 120 shown in example FIG. 2. As shown in example FIGS. 1 and 2, a direction where the line and space of first mask 110 may be formed may intersect with a direction where the line and space of second mask 120 may be formed. An intersection of the line and space of first and second masks 110, 120 may be substantially perpendicular. According to embodiments, and to assist the understanding of embodiments, it may be assumed that the fine pattern may be a rectangular shaped contact hole and the etched film may be an interlayer dielectric film. A design may not be limited thereto. According to embodiments, a fine pattern may have diverse forms other than the contact hole, and the etched film may be diverse kinds of films other than an interlayer dielectric film.

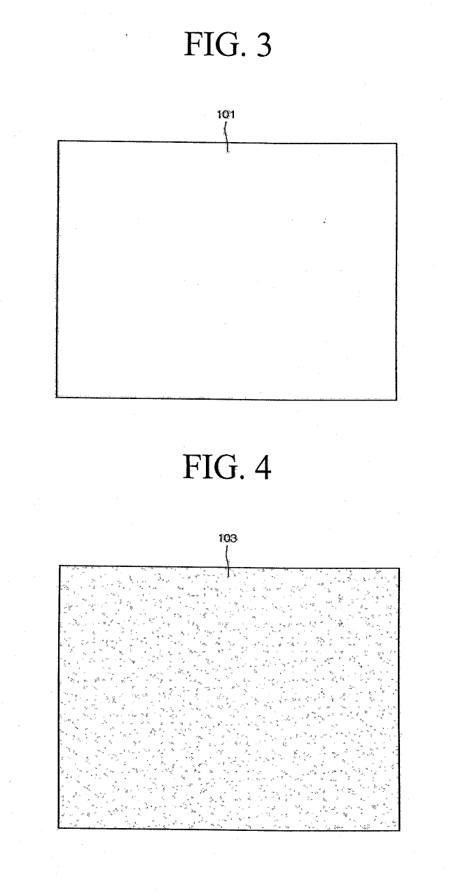

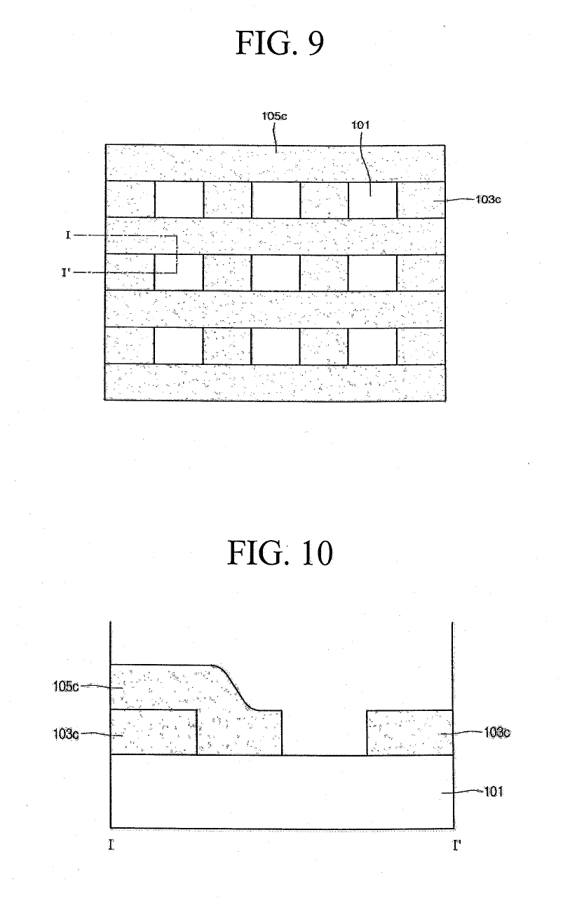

Example FIGS. 3 through 9 are plan views illustrating a process of fabricating a semiconductor device according to embodiments. Example FIG. 10 is a cross-sectional view taken along I-I′ lines of example FIG. 9. Referring to example FIG. 3, interlayer dielectric film 101 may be formed on and/or over an upper portion of a semiconductor substrate. A plurality of transistors, a plurality of wire structures, electronic devices, and dielectric films may be formed on and/or over the semiconductor substrate below interlayer dielectric film 101.

Referring to example FIG. 4, first photoresist film 103 may be formed on and/or over interlayer dielectric film 101. First photoresist film 103 may be made of any one of positive photoresist materiel and negative photoresist material. First photoresist film 103 may be made of a positive photoresist material. According to embodiments, first photoresist film 103 may be made of other photoresist materials.

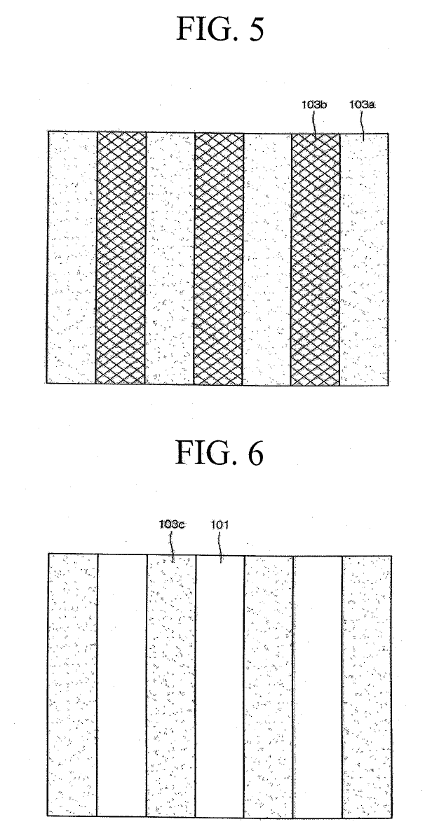

Referring to example FIG. 5, a positive photoresist material may be a material where cross-linking in part 103b that may receive light may be broken to be removed by developer. The negative photoresist material may be a material where cross-linking may be generated in part 103a that may receive light and a part not receiving light may be removed by developer. As shown in example FIGS. 1 and 5, first mask 110 may be spaced apart from first photoresist film 103 at a predetermined interval. Light may then be incident to first mask 110 and may allow the line and space pattern of first mask 110 to be transferred to first photoresist film 103. If the exposed first photoresist film 103 is dipped in a developer or sprayed with a developer, part 103b that may receive light on and/or over first photoresist film 103 may be removed by the developer and part 103a that may not receive light may remain.

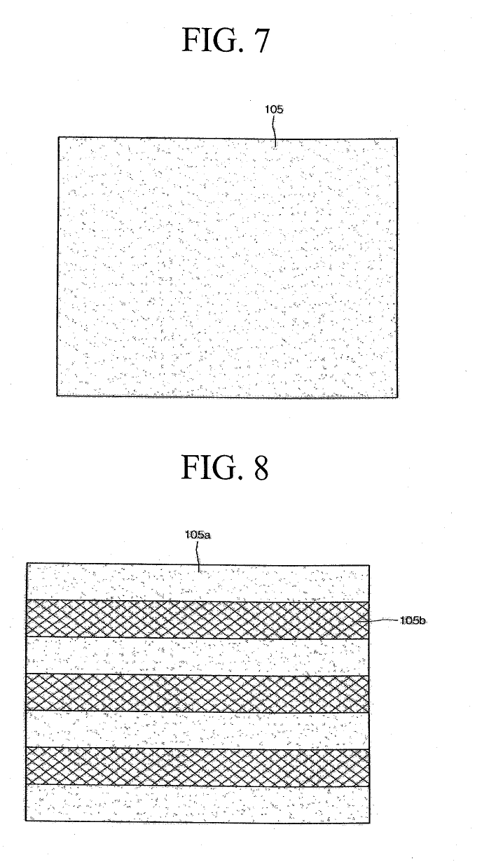

As shown in example FIG. 6, line shaped first photoresist pattern 103c may be formed on and/or over interlayer dielectric film 101. As shown in example FIG. 7, second photoresist film 105 may be formed on and/or over interlayer dielectric film 101 on and/or over which first photoresist pattern 103c may have been formed. Second photoresist film 105 may be made of photoresist material having a different property from first photoresist film 103. Second photoresist film 105 may be made of negative photoresist material. Embodiments may not be limited thereto, however.

As shown in example FIGS. 2 and 8, second mask 120 may be spaced apart from second photoresist film 105 at a predetermined interval. Light may then be incident to second mask 120. This may allow a line and space pattern of second mask 120 to be transferred to second photoresist film 105. If exposed second photoresist film 120 is dipped in a developer or sprayed with a developer, part 105a that may receive light on and/or over second photoresist film 120 may remain. Part 105b that may not receive light may be removed by the developer. This may form a line shaped second photoresist pattern 105c on and/or over the interlayer dielectric film.

Referring to example FIG. 9, first and second photoresist patterns 103c and 105c may be formed on and/or over interlayer dielectric film 101. A line shaped first and second photoresist patterns 103c and 105c may intersect with each other so a portion of interlayer dielectric film 101 may be exposed by first and second photoresist patterns 103c and 105c.

Referring to example FIG. 10, only first photoresist pattern 103c may be formed on and/or over a partial region of interlayer dielectric film 101. According to embodiments, only second photoresist pattern 105c may be formed on and/or over another partial region of interlayer dielectric film 101. First and second photoresist patterns 103c and 105c may be stacked on and/or over another partial region of interlayer dielectric film 101, and interlayer dielectric film 101 may be exposed on and/or over another partial region of interlayer dielectric film 101.

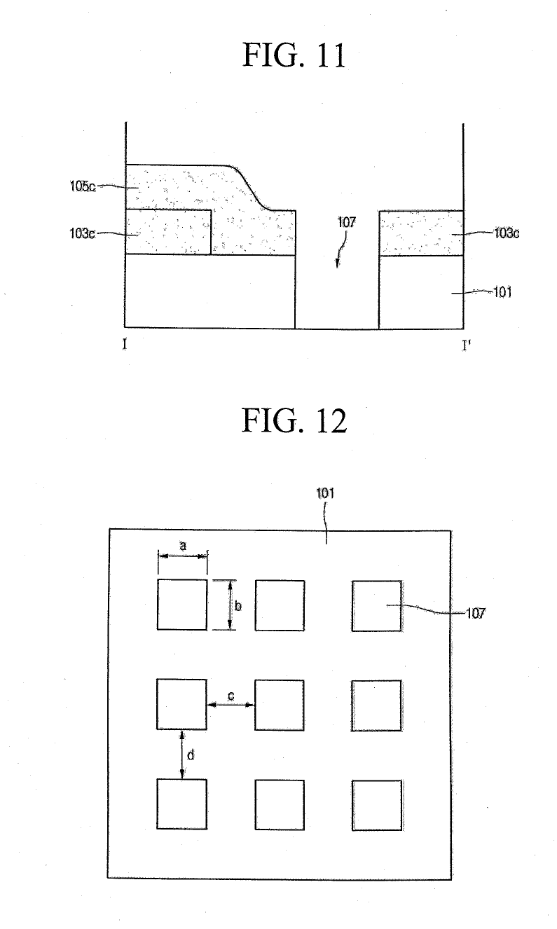

Example FIG. 11 is a cross-sectional view showing a contact hole formed using a method for fabricating a semiconductor device according to embodiments. Example FIG. 12 is a plan view showing an interlayer dielectric film of a semiconductor device fabricated according to embodiments. Referring to example FIGS. 11 and 12, contact hole 107 may be formed by etching interlayer dielectric film 101 using first and second photoresist patterns 103c and 105c as a mask. After contact hole 107 may be formed, first and second photoresist patterns 103c and 105c may be removed using a stripper or the like. A shape of an upper surface of contact hole 107 may have a rectangular cross-section. A shape may be not limited thereto. According to embodiments, the shape may have a circular cross-section. Contact holes 107 may be disposed on and/or over interlayer dielectric film 101 at a predetermined interval.

Horizontal and vertical widths of contact hole 107 may be determined by line and space widths of first and second photoresist patterns 103c and 105c. An interval of contact holes 107 may be determined by line and space widths of first and second photoresist patterns 103c and 105c. Respective horizontal and vertical widths of contact hole 107 may be formed at approximately 30 nm to 100 nm. A size of contact hole 107 may be determined by intervals between first and second photoresist patterns 103c and 105c. According to embodiments, a horizontal width a of contact hole 107 may be determined by a line width of first mask 110. Vertical width b of contact hole 107 may be determined by a width of second mask 120. In the horizontal direction, interval c between contact holes may be determined by a width of first mask 110. In a vertical direction, interval d between contact holes 107 may be determined by a line width of second mask 120. Contact hole 107 fabricated by the method described above may be applied to all of memory, logic, and devices related to CMOS from among the semiconductor device.

According to embodiments, certain effects may be obtained by a method for fabricating a semiconductor device. A fine pattern, such as a contact hole, may be obtained by performing two exposure processes. This may be advantageous in a highly integrated device. Existing masks for line/space for forming the fine pattern may be used, which may make it possible to reduce development costs and investment costs rendered in developing and introducing a method for forming a new pattern. A grade of a photoresist pattern for forming the fine pattern may be excellent, which may prevent defects while an etching process is being performed using the photoresist pattern. This may maximize a yield. A method may secure a sufficient etching margin by securing a sufficient thickness of a photoresist film through two photoresist coating processes. This may make it possible to maximize a degradation of a contact hole and certain device properties.

Although embodiments have been described herein, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A method comprising:
forming first and second photoresist patterns over an etched film, the first and second photoresist patterns configured to intersect with each other; and then
forming a fine pattern over the etched film by etching the etched film using the first and second photoresist patterns as an etching mask.

2. The method of claim 1, wherein a width and spacing of the first and second photoresist patterns determines a width and spacing of the fine pattern.

3. The method of claim 1, wherein the fine pattern comprises a rectangular shaped contact hole.

4. The method of claim 3, wherein a size of the contact hole is approximately 30 nm to 100 nm.

5. The method of claim 1, wherein the first photoresist pattern is formed through exposure and development processes using a first mask, and the second photoresist pattern is formed through exposure and development processes using a second mask, and wherein lines and spaces of the first mask are formed in a first direction, and wherein lines and spaces of the second mask are formed in a second direction that intersects the first direction.

6. The method of claim 5, wherein the intersection of the first and second directions is substantially perpendicular.

7. The method of claim 5, wherein the first mask and the second mask are substantially the same.

8. A method comprising:
forming a dielectric film over a semiconductor substrate; and then
forming and patterning a first photoresist film over the dielectric film to form a first photoresist pattern in a first direction; and then
forming and patterning a second photoresist film over the dielectric film over which the first photoresist pattern is formed to form a second photoresist pattern in a second direction intersecting the first direction; and then
etching the dielectric film using the first and second photoresist patterns as an etching mask.

9. The method of claim 8, wherein the intersection of the first and second directions is substantially perpendicular.

10. The method of claim 8, wherein the each of the first and second photoresist films comprises at least one of a positive photoresist material and a negative photoresist material.

11. The method of claim 10, wherein a material of the first photoresist film is different than a material of the second photoresist film.

12. The method of claim 8, wherein forming and patterning the first photoresist pattern comprises:
forming a first mask having line and space patterns in the first direction over the first photoresist film; and then
selectively exposing the first photoresist film by irradiating light onto the first mask; and then
developing the first photoresist film.

13. The method of claim 12, wherein a width of the line and a width of the space of the first mask is in a range between approximately 30-100 nm.

14. The method of claim 12, wherein forming and patterning the second photoresist pattern comprises:
forming a second mask having line and space patterns in the second direction over the second photoresist film; and then
selectively exposing the second photoresist film by irradiating light onto the second mask; and then
developing the second photoresist film.

15. The method of claim 14, wherein a width of the line and a width of the space of the second mask is in a range between approximately 30-100 nm.

16. The method of claim 8, wherein the dielectric film is etched to form at least one contact hole.

17. The method of claim 16, further comprising forming two contact holes, wherein the two contact holes are disposed over the dielectric film at a predetermined interval.

18. The method of claim 16, wherein a size of the at least one contact hole is determined by spacing intervals of the first and second photoresist patterns.

19. The method of claim 16, further comprising forming two contact holes, wherein an interval between the contact holes is determined by a line width of each of the first and second photoresist patterns.

20. The method of claim 16, wherein a line width of the at least one contact hole is in a range between approximately 30 nm to 100 nm.
